(19) United States
(12) Patent Application Publication
(10) Pub. No.: US 2007/0151098 A1
(43) Pub. Date: Jul. 5, 2007

(54) Extractable electronic apparatus with handle latching structure

(75) Inventors: Yu-Chi Jen, Taoyuan Hsien (TW); Yen-Chun Wang, Taoyuan Hsien (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Delta Electronics, Inc.

(21) Appl. No.: 11/411,623

(22) Filed: Apr. 26, 2006

(30) Foreign Application Priority Data
Jan. 4, 2006 (TW) 095100355

(51) Int. Cl. H05K 3/00; A45C 5/14

(52) U.S. Cl. 29/829; 190/18 A

(57) ABSTRACT

An extractable electronic apparatus with a handle latching structure to be installed in a system equipment having an indentation is disclosed. The extractable electronic apparatus comprises a main body having a first side, a handle unit disposed on the main body and being rotatable relative to the first side, the handle unit having an extending portion, and a latch unit disposed on the first side of the main body and being movable between a first position and a second position of the first side, wherein the handle unit is disengaged from the latch unit while the latch unit is moved to the first position, and the handle unit and the extending portion of the handle unit are engaged with the latch unit and the indentation of the system equipment respectively while the latch unit is moved to the second position for fixing the extractable electronic apparatus in the system equipment.

### FIELD OF THE INVENTION

The present invention relates to an extractable electronic apparatus with a handle, and more particularly to an extractable electronic apparatus with a handle latching structure.

### BACKGROUND OF THE INVENTION

With the popularity of technology, the large-sized system equipments are widely used for network communication and information access and analysis. For driving most of the system equipments, electricity is the indispensable power source and thus the power supply is applied to all kinds of electronic products. An extractable power supply has been developed and used in the system equipments, such as network communication equipment, industrial computer, server, and disk array, for supplying sufficient and continuing electric power. Generally, a handle unit is designed for the extractable power supply for users to apply force easily to draw out the extractable power supply or insert it into the system equipment.

Please refer to FIG. 1, which is a schematic diagram showing the conventional extractable power supply. As shown in FIG. 1, the conventional extractable power supply 1 comprises a casing 11 and an immovable handle unit 12, wherein a circuit board assembly (not shown) is disposed in the casing 11 and the immovable handle unit 12 is disposed on a surface 13 of the casing 11 for the user to apply force conveniently to draw out or insert the conventional extractable power supply 1. Though the design and the use of the immovable handle unit 12 of the conventional extractable power supply 1 is uncomplicated, no simple and effective fixing mechanism is devised for installing the conventional extractable power supply 1 in the system equipment firmly. Hence the conventional extractable power supply 1 may be drawn out inattentively by the staff while the system equipment is still working. The power failure may cause the shutdown of the system equipment and further cause the huge losses of the cost.

Besides, the immovable handle unit 12 is disposed on the surface 13 of the casing 11 and cannot be folded or received when the conventional extractable power supply 1 is installed in the system equipment. Therefore the whole volume of the system equipment is enlarged owing to the exposed immovable handle unit 12.

Accordingly, it is required to develop an extractable electronic apparatus with a handle latching structure to overcome the foregoing defects.

### SUMMARY OF THE INVENTION

An object of the present invention is to provide an extractable electronic apparatus with a handle latching structure to fix the handle unit tightly to the main body of the extractable electronic apparatus while not being used; meantime, the extractable electronic apparatus can be installed in the system equipment firmly, so as to avoid being drawn out inattentively.

Another object of the present invention is to provide an extractable electronic apparatus with a handle latching structure to reduce the volume of the extractable electronic apparatus and save more space for further utilization by attaching the handle unit close to the main body of the extractable electronic apparatus while the handle unit is not being used.

According to an aspect of the present invention, an extractable electronic apparatus with a handle latching structure to be installed in a system having an indentation is provided. The extractable electronic apparatus with the handle latching structure comprises: a main body having a first side; a handle unit disposed on the main body and being rotatable relative to the first side, the handle unit having an extending portion; and a latch unit disposed on the first side of the main body and being movable between a first position and a second position of the first side; wherein the handle unit is disengaged from the latch unit while the latch unit is moved to the first position, and the handle unit and the extending portion of the handle unit are engaged with the latch unit and the indentation of the system respectively while the latch unit is moved to the second position for fixing the extractable electronic apparatus in the system.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic diagram showing the conventional extractable power supply;

FIGS. 2(a) and 2(b) are schematic diagrams showing the extractable electronic apparatus according to the first preferred embodiment of the present invention while the handle unit is disengaged from and engaged with the latch unit respectively;

FIGS. 3(a) and 3(b) are schematic diagrams showing the cross-sections of the extractable electronic apparatus shown in FIGS. 2(a) and 2(b) respectively;

FIGS. 4(a) and 4(b) are schematic diagrams showing the extractable electronic apparatus shown in FIGS. 2(a) and 2(b) respectively with a cover;

FIGS. 5(a) and 5(b) are schematic diagrams showing the extractable electronic apparatus according to the second preferred embodiment of the present invention while the handle unit is disengaged from and engaged with the latch unit respectively; and

FIGS. 6(a) and 6(b), which are schematic diagrams showing the cross-sections of the extractable electronic apparatus shown in FIGS. 5(a) and 5(b) respectively.

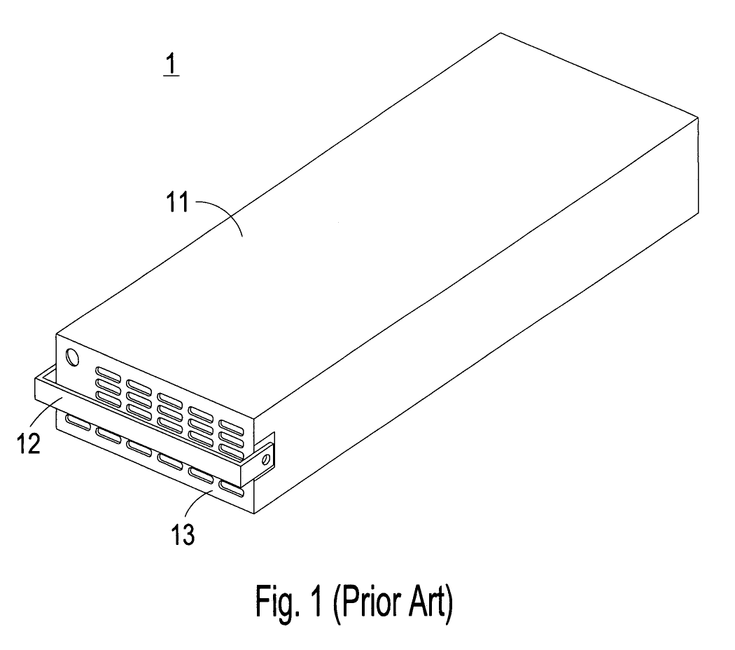

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

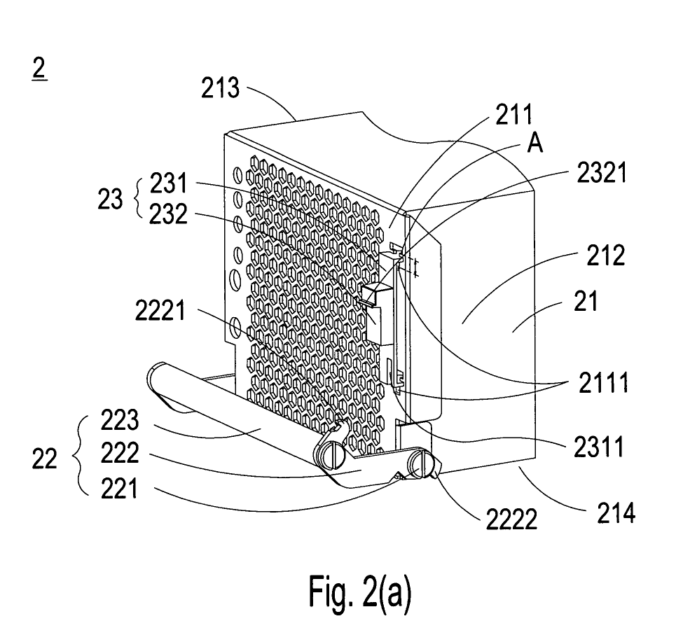

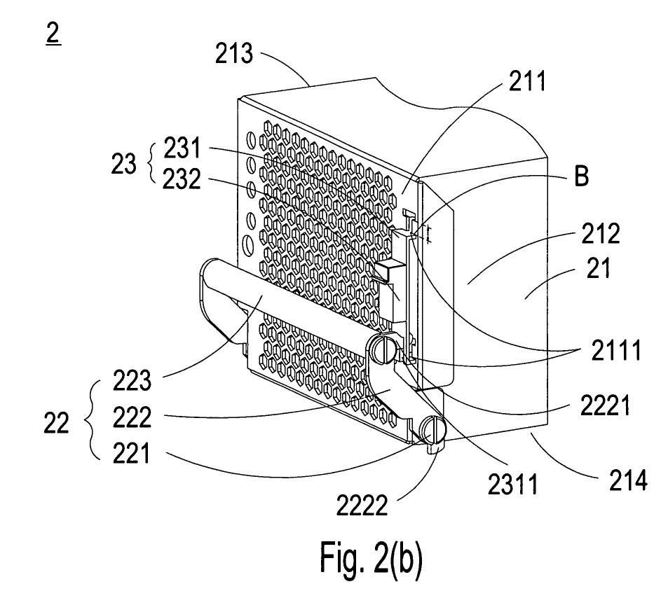

Please refer to FIGS. 2(a) and 2(b), which are schematic diagrams showing the extractable electronic apparatus according to the first preferred embodiment of the present invention while the handle unit is disengaged from the latch unit and engaged with the latch unit respectively. As shown in FIGS. 2(a) and 2(b), the extractable electronic apparatus 2 can be an extractable power supply or an extractable storage apparatus, but not limited thereto. The extractable electronic apparatus 2 comprises a main body 21, a handle unit 22, and a latch unit 23. The main body 21 has a first side 211, a second side 212, a third side 213, and a bottom side 214, wherein the second side 212 and the third side 213 are disposed at the opposite laterals of the first side 211 respectively. The handle unit 22 includes a shaft 221, a side plate 222, and a grip 223. The shaft 221 is disposed on the opposite laterals of the first side 211, in other words, the shaft 221 is disposed on the second side 212 and the third side 213. The side plate 222 is axially rotatable relative to the second side 212 and/or the third side 213 via the shaft 221. In addition, the grip 223 is connected to the side plate 222 for the user to hold and apply force thereon, so as to move the handle unit 22 relative to the first side 211 of the main body 21.

In an embodiment, the side plate 222 further comprises a hook 2221 and an extending portion 2222. The hook 2221 is disposed at one end of the side plate 222 or other place for engaging with the latch unit 23, and the extending portion 2222 is disposed on the other end of the side plate 222 or other place for engaging with the corresponding indentation (not shown) of the system equipment, so as to install the extractable electronic apparatus 2 in the system equipment firmly. Preferably, the side plate 222 is substantially an L-shaped structure, but not limited thereto.

Please refer to FIGS. 2(a) and 2(b) again. The latch unit 23 is disposed on the first side 211 of the main body 21 and is movable between the first position A and the second position B on the first side 211 of the main body 21, and thus the handle unit 22 can be disengaged from the latch unit 23 (as shown in FIG. 2(a)) or engaged with the latch unit 23 (as shown in FIG. 2(b)) respectively. The latch unit 23 further comprises a slide 231 with two opposite ends extending perpendicularly toward the groove 2111 on the first side 211 and disposed therein. Thus the slide 231 is able to be moved between the first position A and the second position B along the first side 211. In an embodiment of the present invention, a block 232 with a force applying portion 2321 is disposed on the surface of the slide 231, wherein the user can apply the force to the force applying portion 2321 to move the slide 231 along the first side 211 of the main body 21. Moreover, the slide 231 further comprises a hook slit 2311 which can be engaged with the hook 2221 of the handle unit 22.

Please refer to FIG. 2(a) again. With the movement of the handle unit 22, the hook 2221 can be freely moved in and out of the hook slit 2311 without any obstruction when a force is applied to the block 232 to move the slide 231 to the first position A; in other words, the handle unit 22 and the latch unit 23 are disengaged. While as shown in FIG. 2(b), the hook 2221 of the handle unit 22 is engaged with the hook slit 2311 of the latch unit 23 when a force is applied to move the handle unit 22 toward the first side 211 for receiving the hook 2221 into the hook slit 2311 and the latch unit 23 is moved to the second position B. Hence the handle unit 22 can stay close to the main body 21 by being engaged with the latch unit 23 and thus the purpose for receiving the handle unit 22 to the main body 21 of the extractable electronic apparatus 2 can be accomplished. Furthermore, the extending portion 2222 of the handle unit 22 is protruded out of the bottom side 214 of the main body 21 and engaged with the corresponding indentation (not shown in FIG. 2(b)) of the system equipment because the side plate 222 is rotated along the shaft 221 while engaging the handle unit 22 with the latch unit 23; hence the extractable electronic apparatus 2 is installed firmly in the system equipment.

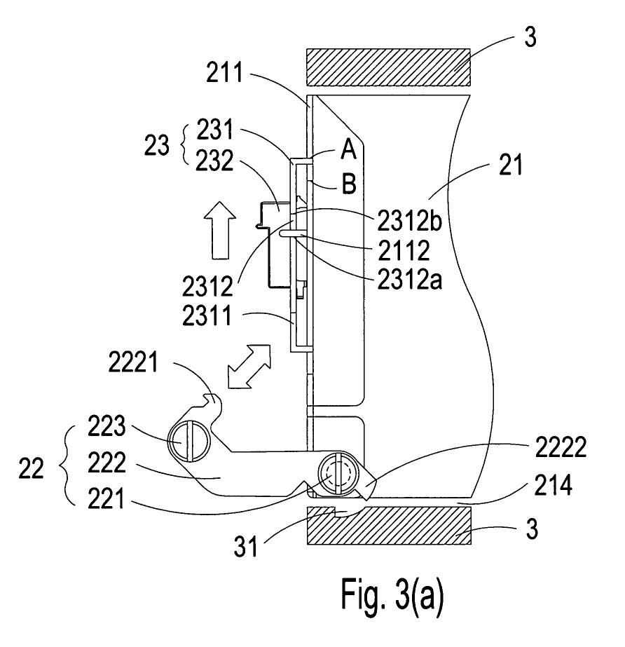

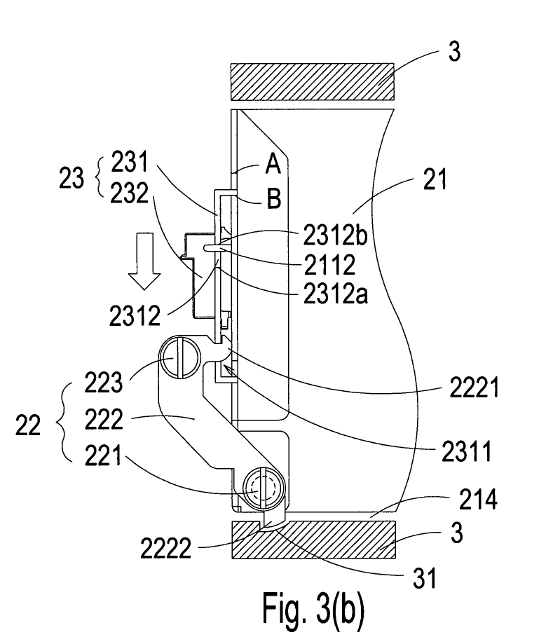

Please refer to FIGS. 3(a) and 3(b), which are schematic diagrams showing the cross-sections of the extractable electronic apparatus shown in FIGS. 2(a) and 2(b) respectively. As shown in FIG. 3(a), while the main body 21 is going to be inserted in or drawn out from the system equipment 3, the latch unit 23 is moved upwardly to the first position A, so the handle unit 22 is disengaged from the latch unit 23 and can be rotated away from the first side 211 of the main body 21, and thus a sufficient space is formed for the user to hold the grip 223 to insert or draw the extractable electronic apparatus 2. Meanwhile, the extending portion 2222 of the side plate 222 is returned to the bottom side 214 of the main body 21 without protruding thereout, and thus disengaged from the indentation 31 of the system equipment 3; therefore the extractable electronic apparatus 2 can be inserted in or drawn out from the system equipment 3 freely.

Please refer to FIG. 3(b). While the main body 21 is substantially inserted in the system equipment 3, the handle unit 22 is moved toward the first side 211 for receiving the hook 2221 of the handle unit 22 in the hook slit 2311 of the latch unit 23, and the slide 231 of the latch unit 23 is moved downward to the second position B, so as to secure the handle unit 22 close to the main body 21. Meantime, the extending portion 2222 is protruded out of the bottom side 214 of the main body 21 and engaged with the indentation 31 of the system equipment 3 by rotating the side plate 222 along the shaft 221 while engaging the handle unit 22 and the latch unit 23, and thus the extractable electronic apparatus 2 can be aligned with the system equipment 3 precisely and installed in the system equipment 3 firmly.

Please refer to FIGS. 3(a) and 3(b) again. The first side 211 and the slide 231 further comprise a protrusion 2112 and a guiding trench 2312 respectively for the slide 231 of the latch unit 23 to be moved between the first position A and the second position B. When the slide 231 is moved to the first position A, the protrusion 2112 is against one end 2312a of the guiding trench 2312 (as shown in FIG. 3(a)); while the slide 231 is moved to the second position B, the protrusion 2112 is against the other end 2312b of the guiding trench 2312 (as shown in FIG. 3(b)). In some embodiments, the protrusion 2112 can be replaced by the screw, and the side plate 222 of the handle unit 22 can be integrally formed with the grip 223, but not limited thereto.

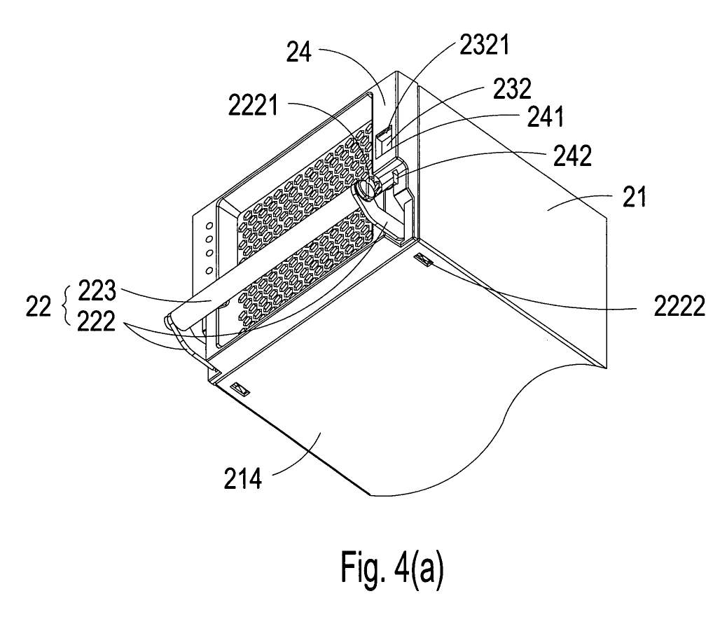

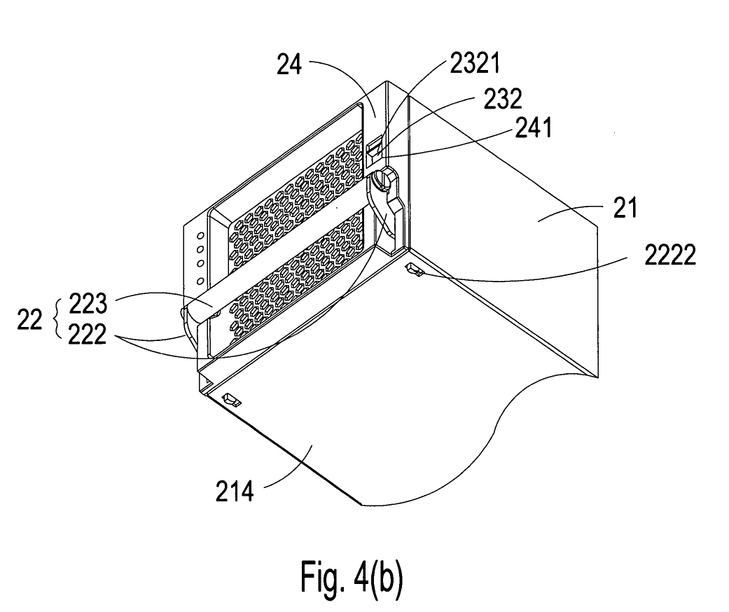

Please refer to FIGS. 4(a) and 4(b), which are schematic diagrams showing the extractable electronic apparatus shown in FIGS. 2(a) and 2(b) respectively with a cover. The cover 24 shelters the first side 211 of the main body 21 and the latch unit 23 and exposes parts of the handle unit 22. The cover 24 comprises an opening 241 and a ditch 242, wherein the opening 241 is aligned with the block 232 of the latch unit 23 for exposing the force applying portion 2321 of the block 232 to be moved therein. Moreover, the ditch 242 is aligned with the hook slit 2311 of the latch unit 23. The force applying portion 2321 of the latch unit 23 is exposed out of the cover 24 through the opening 241; hence the user can apply the force to the force applying portion 2321 so as to move the latch unit 23 for disengaging from or engaging with the handle unit 22. The extending portion 2222 is protruded out of the bottom side 214 of the main body 21 and engaged with the corresponding indentation (not shown) of the system equipment while the side plate 222 is rotated along the shaft 221 while engaging the hook 2221 and the hook slit 2311, so as to install the extractable electronic apparatus 2 in the system equipment 3 firmly.

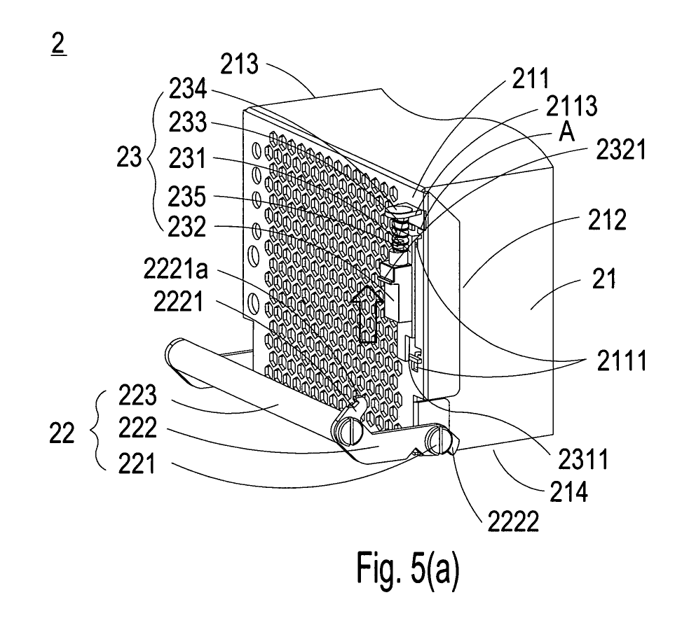

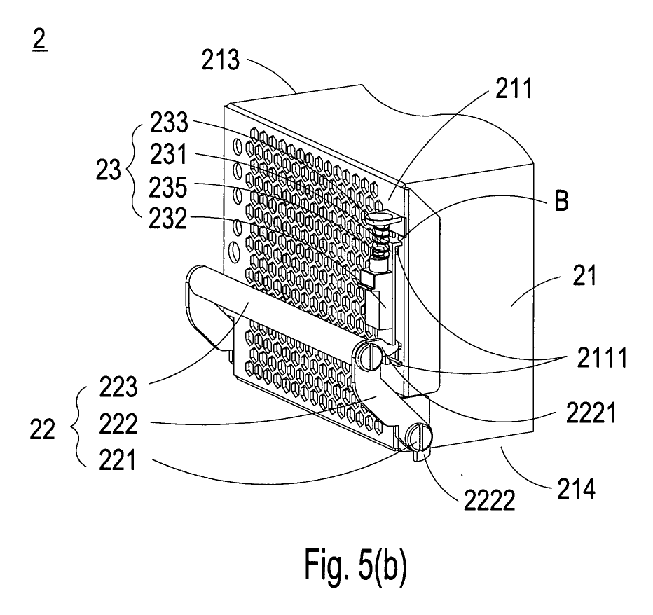

Please refer to FIGS. 5(a) and 5(b), which are schematic diagrams showing the extractable electronic apparatus according to the second preferred embodiment of the present invention while the handle unit is disengaged from and engaged with the latch unit respectively. As shown in these figures, the functions and the structures of the main body 21, the handle unit 22, and the latch unit 23 are similar to those of the first embodiment and thus no longer described in details. In this embodiment, an elastic device 233 is optionally included in the latch unit 23, and an ear member 2113 is disposed on the first side 211 of the main body 21 near the top of the latch unit 23. One end of the elastic device 233 is connected to the ear member 2113 directly or through a connecting device 234 while the other end of the elastic device 233 is connected to one lateral of the block 232 directly or to the projection 235 on the lateral of the block 232. The slide 231 of the latch unit 23 is held at the second position B owing to the elasticity of the elastic device 233. When the extractable electronic apparatus 2 is going to be inserted in or drawn out from the system equipment, the user only needs to apply a force to the force applying portion 2321 of the block 232 to move the latch unit 23 upwardly to the first position A and rotate the handle unit 22 away from the first side 211, so as to disengage the hook 2221 of the handle unit 22 from the hook slit 2311 of the latch unit 23. At the same time, as shown in FIG. 5(a), the extending portion 2222 is returned to the bottom side 214 of the main body 21 without protruding thereout; hence the user can insert or draw the extractable electronic apparatus 2 easily. Of course, when the user releases the force applying portion 2321, the elastic device 233 is against the block 232 therefore the slide 231 is moved back to the second position B due to the elasticity.

Please refer to FIG. 5(b). When the main body 21 of the extractable electronic apparatus 2 is going to be installed in the system equipment, the main body 21 is inserted into the system equipment and the handle unit 22 is rotated toward the first side 211 of the main body 21. Because the hook 2221 further comprises an incline 2221a (shown in FIG. 5(a)), the slide 231 is moved toward the first position A slightly while the incline 2221a is against the wall of the hook slit 2311 of the slide 231. After the hook 2221 is received in the hook slit 2311, the slide 231 is moved back to the second position B by the elasticity of the elastic device 233 against the block 232, so as to engage the hook 2221 and the hook slit 2311 for securing the handle unit 22 close to the main body 21. Of course, the force can be applied to the force applying portion 2321 to move the slide 231 upwardly to the first position A and rotate the handle unit 22 toward the first side 211 of the main body 21 until the hook 2221 is received in the hook slit 2311; at the same time, the hook 2221 and the hook slit 2311 are engaged together after the force applying portion 2321 is released by the user and the slide 231 is moved back to the second position B owing to the elasticity of the elastic device 233 against the block 232. Meanwhile, the extractable electronic apparatus 2 is installed in the system equipment firmly through the extending portion 2222 protruding out of the bottom side 214 of the main body 21 and engaging with the corresponding indentation of the system equipment while the side plate 222 is rotated toward the first side 211.

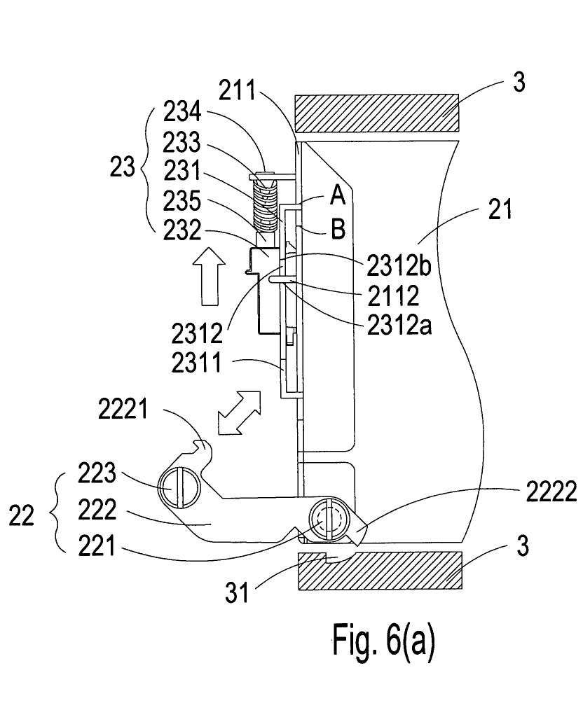

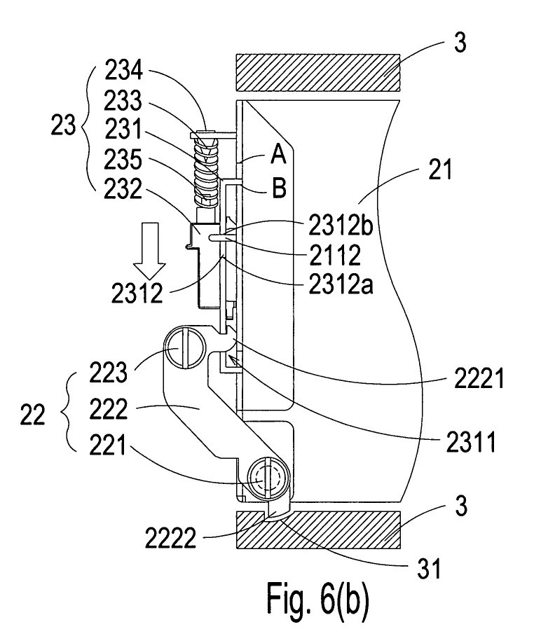

Please refer to FIGS. 6(a) and 6(b), which are schematic diagrams showing the cross-sections of the extractable electronic apparatus shown in FIGS. 5(a) and 5(b). As shown in FIG. 6(a), while the main body 21 is going to be inserted in or drawn out from the system equipment 3, the latch unit 23 is moved upwardly to the first position A; therefore the handle unit 22 is disengaged from the latch unit 23 and can be rotated away from the first side 211 of the main body 21, and thus a sufficient space is formed for the user to hold the grip 223 for inserting or drawing the extractable electronic apparatus 2. Meanwhile, the extending portion 2222 of the side plate 222 is returned to the bottom side 214 of the main body 21 without protruding thereout and disengaged from the indentation 31 of the system equipment 3; hence the extractable electronic apparatus 2 can be inserted in or drawn out from the system equipment 3 freely.

Please refer to FIG. 6(b). When the main body 21 is substantially disposed in the system equipment 3, the handle unit 22 can be rotated toward the first side 211 so as to receive the hook 2221 of the side plate 222 in the hook slit 2311 of the latch unit 23. At the same time, the slide 231 is moved to the second position B by means of the elasticity of the elastic device 233 against the block 232, so as to engage the hook 2221 with the hook slit 2311 and secure the handle unit 22 close to the main body 21. The extending portion 2222 is protruded out of the bottom side 214 of the main body 21 and engaged with the indentation 31 of the system equipment 3 by rotating the side plate 222 along the shaft 221 while engaging the handle unit 22 and the latch unit 23, and thus the extractable electronic apparatus 2 can be aligned with the system equipment 3 precisely and installed in the system equipment 3 firmly.

Please refer to FIGS. 6(a) and 6(b) again. The first side 211 and the slide 231 further comprise a protrusion 2112 and a guiding trench 2312 respectively for the slide 231 of the latch unit 23 to be moved between the first position A and the second position B. The protrusion 2112 is against the opposite ends 2312a and 2312b of the guiding trench 2312 while the slide 231 is moved to the first position A and the second position B respectively.

Similarly, in this embodiment, a cover 24 can be further disposed on the extractable electronic apparatus 2 as shown in FIGS. 4(a) and 4(b). The cover 24 shelters the first side 211 of the main body 21 and the latch unit 23 and exposes parts of the handle unit 22. The cover 24 comprises an opening 241 for the force applying portion 2321 to be moved therein and a ditch 242 aligned with the hook slit 2311 of the latch unit 23. The force applying portion 2321 is exposed out of the cover 24 through the opening 241; hence the user can apply the force to the force applying portion 2321 so as to move the latch unit 23 for disengaging or engaging the handle unit 22 and the latch unit 23. Of course, the extending portion 2222 is protruded out of the bottom side 214 of the main body 21 and engaged with the corresponding indentation of the system equipment via the movement of the handle unit 22 while engaging the hook 2221 and the hook slit 2311.

To sum up, the handle unit can be engaged with the main body of the extractable electronic apparatus tightly to avoid falling out while not being used. In addition, the extractable electronic apparatus is installed in the system equipment firmly while the handle unit is engaged with the latch unit of the main body, so as to keep the extractable electronic apparatus from being drawn out inattentively by the user. Besides, the handle unit can be secured close to the main body while not being used, and the volume of the extractable electronic apparatus is reduced for higher space utilization.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An extractable electronic apparatus with a handle latching structure to be installed in a system equipment having an indentation, said extractable electronic apparatus comprising:
a main body having a first side;
a handle unit disposed on said main body and being rotatable relative to said first side, said handle unit having an extending portion; and
a latch unit disposed on said first side of said main body and being movable between a first position and a second position of said first side;
wherein said handle unit is disengaged from said latch unit while said latch unit is moved to said first position, and said handle unit and said extending portion of said handle unit are engaged with said latch unit and said indentation of said system equipment respectively while said latch unit is moved to said second position for fixing said extractable electronic apparatus in said system equipment.

2. The extractable electronic apparatus with the handle latching structure according to claim 1 wherein said main body further comprises a second side, a third side, and a bottom side, and said second side and said third side are disposed at opposite laterals of said first side.

3. The extractable electronic apparatus with the handle latching structure according to claim 2 wherein said handle unit further comprises:
a shaft disposed on said second side and/or said third side of said main body;
a side plate axially connected to said main body via said shaft, said side plate having a hook and said extending portion; and
a grip connected to said side plate.

4. The extractable electronic apparatus with the handle latching structure according to claim 3 wherein said side plate is substantially an L-shaped structure.

5. The extractable electronic apparatus with the handle latching structure according to claim 3 wherein said hook and said extending portion are disposed on opposite ends of said side plate.

6. The extractable electronic apparatus with the handle latching structure according to claim 5 wherein said first side of said main body further comprises a groove.

7. The extractable electronic apparatus with the handle latching structure according to claim 6 wherein said latch unit comprises:
a slide disposed on said first side and having a hook slit thereon, said slide being slidable in said groove and movable between said first position and said second position for disengaging said hook from said hook slit or engaging said hook with said hook slit; and
a block disposed on said slide and having a force applying portion thereon.

8. The extractable electronic apparatus with the handle latching structure according to claim 7 wherein said hook of said handle unit is disengaged from said hook slit of said latch unit while a force is applied on said block to move said slide to said first position.

9. The extractable electronic apparatus with the handle latching structure according to claim 7 wherein said hook of said handle unit is engaged with said hook slit of said latch unit while said hook is received in said hook slit and said latch unit is moved to said second position by forcing said handle unit and said latch unit respectively.

10. The extractable electronic apparatus with the handle latching structure according to claim 7 wherein said extending portion of said handle unit is protruded out of said bottom side of said main body and engaged with said indentation of said system equipment while said handle unit is engaged with said latch unit.

11. The extractable electronic apparatus with the handle latching structure according to claim 7 wherein said first side of said main body further comprises a protrusion, and said slide of said latch unit further comprises a guiding trench for receiving said protrusion.

12. The extractable electronic apparatus with the handle latching structure according to claim 11 wherein said protrusion is against opposite ends of said guiding trench while said slide is moved to said first position and said second position respectively.

13. The extractable electronic apparatus with the handle latching structure according to claim 7 further comprising a cover disposed on said first side of said main body for covering said latch unit and exposing parts of said handle unit.

14. The extractable electronic apparatus with the handle latching structure according to claim 13 wherein said cover further comprises an opening and a ditch, said opening is aligned with said block of said latch unit for enabling said force applying portion of said block to move therein, and said ditch is aligned with said hook slit of said latch unit.

15. The extractable electronic apparatus with the handle latching structure according to claim 7 wherein said latch unit further comprises an elastic device, and said first side of said main body further comprises an ear member substantially near a top of said latch unit.

16. The extractable electronic apparatus with the handle latching structure according to claim 15 wherein one end of said elastic device is connected to said ear member directly or via a connecting device, and the other end of said elastic device is connected to a lateral of said block directly or via a projection disposed on a lateral of said block.

17. The extractable electronic apparatus with the handle latching structure according to claim 16 wherein said hook of said handle unit further comprises an incline.

18. The extractable electronic apparatus with the handle latching structure according to claim 1 being a power supply.
